(19) United States
(12) Patent Application Publication
(10) Pub. No.: US 2009/0159912 A1
(43) Pub. Date: Jun. 25, 2009

(54) HOUSING FOR A LUMINESCENCE DIODE COMPONENT

(75) Inventors: Moritz Engl, Regensburg (DE); Joachim Reill, Zeitlarn (DE); Martin Wüller, Warendorf (DE); Lukas Schwenkschuster, Burgstetten (DE)

Correspondence Address: FISH & RICHARDSON PC, P.O. BOX 1022, MINNEAPOLIS, MN, 55440-1022, US

(73) Assignee: OSRAM OPTO SEMICONDUCTORS GMBH, Regensburg (DE)

(21) Appl. No.: 12/162,161

(22) PCT Filed: Jan. 24, 2007
(86) PCT No.: PCT/DE07/00129

§ 371 Date: Oct. 15, 2008

(30) Foreign Application Priority Data
Feb. 6, 2006 (DE) 10 2006 005 299.4

(51) Int. Cl. H01L 33/00

(52) U.S. Cl. 257/98; 257/99; 257/E33.001

(57) ABSTRACT

What is specified is a housing for a luminescence diode component comprising a housing cavity within which is arranged at least one chip mounting region for a luminescence diode chip and which has an output opening. In accordance with one embodiment, the housing has, at least at a vertical distance from the chip mounting region, inner walls which laterally bound the housing cavity and are at a maximum lateral distance of less than or equal to 500 μm from the chip mounting region. What is additionally specified is a housing in which the housing cavity has at least one partial region which is laterally covered by a housing material that laterally delimits the housing cavity. Moreover, a description is given of a luminescence diode component, in particular for a motor vehicle headlight.

### CROSS-REFERENCE TO RELATED APPLICATIONS

This patent application is the National Stage of International Application No. PCT/DE2007/000129 filed on Jan. 24, 2007, which claims the priority of German Patent Application 102006005299.4, filed on Feb. 6, 2006, the entire contents of which are hereby incorporated by reference.

### TECHNICAL FIELD

The present disclosure relates to a housing for a luminescence diode component and to a luminescence diode component comprising a housing of this type. It relates, in particular, to a housing for a headlight component which emits white light.

### BACKGROUND

Housings for optoelectronic components that emit electromagnetic radiation comprising a basic body that defines a housing cavity are known. The bottom of said housing cavity is provided for mounting a luminescence diode chip. Inner walls that laterally delimit the housing cavity may be shaped in the manner of a reflector, with the result that a portion of an electromagnetic radiation emitted by the luminescence diode chip can be deflected into a desired beam solid angle by means of the inner walls. A component having a housing of this type is disclosed for example in DE 297 24 543 U1.

The light-emitting semiconductor component described in said document has a luminescence conversion element. A luminescence diode chip of the component emits an electromagnetic radiation of a first wavelength range, which is partly converted into a radiation of a second wavelength range by the luminescence conversion element. If the first wavelength range comprises blue light and the second wavelength range comprises yellow light, white light can thus be generated for example by additive colour mixing.

If the path lengths of the electromagnetic radiation emitted by the luminescence diode chip, by virtue of the luminescence conversion element, are different in length depending on the emission angle, a light proportion of varying magnitude is converted depending on the path length. This may have the effect that the colour of a light cone emitted by the component is inhomogeneous. By way of example, the edge regions of a beam cone when using a yellow phosphor may have a significantly higher yellow component than central regions of the beam cone.

DE 297 24 543 U1 specifies luminescence conversion elements in the form of a thin layer of uniform thickness. Said layer may be arranged directly onto the luminescence diode chip or at a distance from the luminescence diode chip in the beam path of the component. Colour inhomogeneities can be significantly reduced by means of such luminescence conversion elements embodied as a thin layer.

Luminescence diode components are being employed more and more often in headlight or projection applications. An example of a headlight in which luminescence diode chips that emit electromagnetic radiation are used is specified in DE 103 151 31 A1. This concerns a headlight for vehicles in which a plurality of luminescence diode chips are arranged in a common cut-out. The cut-out has, on a side that faces in the light emission direction, an edge margin that is in spatial arrangement with respect to the luminescence diode chips in such a way that a predetermined luminance gradient for a light distribution of the headlight is formed in the region of the edge margins. The beam cone is projected onto a desired plane by means of optics such as projection lenses.

Particularly in headlight applications for motor vehicles, not only the realization of a predetermined luminescence distribution of the beam cone but also colour rendering that is as uniform as possible is of importance, where colour irregularities in the emitted headlight cone can have a disturbing effect.

### SUMMARY

It is an object to specify a housing of the type mentioned in the introduction with which a luminescence diode component having low colour inhomogeneities of an emitted light cone can be realized in a technically simple manner using a luminescence conversion material. In this case, the housing is intended to be suitable in particular also for headlight or projection applications. Moreover, the intention is to specify a component having a housing of this type and corresponding properties.

A housing is specified whose housing cavity has at least one partial region that is laterally covered by a housing material that laterally delimits the housing cavity. Preferably, the partial region is also offset laterally with respect to the output opening. Laterally is to be understood to mean a direction parallel to a chip mounting plane of the chip mounting region.

The partial region of the housing cavity is shaded by housing material. A component having high colour homogeneity can thereby be realized in a technically simple manner using a luminescence conversion material. Moreover, the shading of the partial region may serve to set a desired luminescence distribution of the light cone emitted by the component to be produced. In particular asymmetrical luminescence distributions can thus be realized in an advantageous manner.

Expediently, the laterally covered partial region of the housing cavity adjoins a chip mounting plane of the housing.

A housing for a luminescence diode component of the type mentioned in the introduction is specified which has at least at a vertical distance from the chip mounting region, inner walls which laterally bound the housing cavity and are at a maximum lateral distance of less than or equal to 500 μm from the chip mounting region. The housing may additionally have one or more of the features described above or below.

In particular, the inner walls enclose the housing cavity laterally. In other words, the housing cavity has, at a distance from the chip mounting region, a section which is very narrow in a lateral direction and whose lateral extent is not very much larger than the chip mounting region, that is to say than the lateral extent of the luminescence diode chip provided for the housing.

In the case where a plurality of chip mounting regions are present in a linear arrangement in the housing and the housing cavity has an extended form in a plan view, then it suffices for the inner walls to be at the specified maximum distances from a closest chip mounting region only at the longitudinal sides. The inner walls at the transverse sides may also be at a larger lateral distance from the closest chip mounting region.

It has been established that luminescence diode components having a low colour inhomogeneity can be realized by means of such a configuration of the housing or the housing cavity even when the housing cavity is not only provided with a luminescence conversion material in the form of a thin, uniform layer, but when it is filled with a luminescence conversion material in the form of a volume potting. The potting encapsulates the luminescence diode chip, in particular.

Moreover, it has been established that housings of this type may be well suited to headlight applications, particularly if inhomogeneous luminescence distributions are to be realized. With the housing, it is accordingly possible to produce, in particular, components comprising a luminescence conversion material which both have a high colour homogeneity and advantageously enable predetermined inhomogeneous luminescence distributions of a light cone to be generated.

The inner walls of the housing cavity preferably run essentially perpendicular to the chip mounting plane, at least in the region of the narrow section.

The inner walls are at the small lateral distance from the chip mounting region at least at a vertical distance of greater than or equal to 300 μm, preferably of greater than or equal to 500 μm, from the chip mounting plane. In accordance with a particularly preferred embodiment, a housing margin that bounds the output opening is at a maximum lateral distance of less than or equal to 500 μm from the chip mounting region.

The maximum lateral distance between the inner walls or the margin and the chip mounting region is particularly preferably less than or equal to 350 μm. Along at least one main side, said lateral distance of the inner walls or the margin is advantageously a maximum of 200 μm, preferably a maximum of 150 μm, from the chip mounting region. A housing generally has four main sides, in particular a housing having an e.g. essentially square or rectangular form.

In accordance with one preferred embodiment, the housing cavity contains an electrical contact area for electrically conductively contact-connecting a luminescence diode chip, said contact area being at least partly covered by the housing material that laterally delimits the housing cavity. Electrical contact areas of this type may serve in particular for electrically conductively contact-connecting luminescence diode chips by means of a bonding wire. By means of the electrical contact area being at least partly arranged in the covered region, the available space in the housing cavity can be utilized skilfully and a small lateral extent of the rest of the housing cavity can be realized.

In accordance with a further advantageous embodiment, in addition or as an alternative, a part of the chip mounting region is laterally covered by the housing material that laterally delimits the housing cavity. In the context of the present application, the chip mounting region is to be understood to mean a region which is intended to be filled by a luminescence diode chip in a component. A partial covering of the chip mounting region therefore also results in a partial covering of a luminescence diode chip in the component to be produced, with the result that generally a part of the light-emitting layer of the luminescence diode chip is also laterally shaded in the component. It is thereby possible to realize a light cone which has a particularly high luminescence, and in particular a very steep luminescence gradient, on the side at which the luminescence diode chip is partially shaded. This is advantageous particularly in headlight applications for motor vehicles.

Preferably, the housing has a plurality of chip mounting regions arranged in a linear arrangement with respect to one another. Expediently, the cavity is embodied in trench-like fashion in this case and has an extended form in particular in a plan view. With a housing embodied in this way, it is possible to realize a component which emits a radiation cone that is advantageous for many applications. The radiation cone may have a cross section having a relatively large length and a small width in comparison therewith, which is advantageous for the application in automobile headlights, for example, in which vertically a relatively small solid angle, but horizontally the carriageway in its entire width, that is to say a relatively large solid angle, is to be illuminated.

The housing advantageously has a frame that laterally delimits the housing cavity, said frame being embodied in light-tight fashion and, in particular, comprising a light-tight material. Particularly preferably, however, as an alternative to this embodiment, the housing has a frame that laterally delimits the housing cavity and is at least partly light-transmissive. What can thereby be achieved is that a portion of the light generated in the housing is likewise emitted via the housing frame, with the result that a component having a radiation cone which has relatively gentle bright-dark transitions can be realized even in the case of a relatively narrow housing cavity.

The frame expediently has a transmissivity of light of greater than or equal to 20% in a lateral direction. In addition or as an alternative, the transmissivity of the frame is advantageously less than or equal to 80%. In accordance with a further expedient embodiment, the housing has a housing part which laterally covers a partial region of the housing cavity and which has a transmissivity to light of greater than or equal to 20% and/or less than or equal to 80% in a vertical direction. In principle, it is also possible to use an almost completely light-transmissive material such as, for example, light-transmissive glass for the frame, with the result that the frame has a transmissivity to light of greater than 80% in a lateral direction.

One advantageous embodiment of the housing provides for an outer area of the housing which adjoins the output opening of the housing cavity to be provided with a screening layer. The screening layer is suitable for screening an electromagnetic radiation, provision being made, in particular for externally screening an electromagnetic radiation that is generated or to be generated in the interior of the housing. As a result, an emergence of electromagnetic radiation from the housing into undesirable solid angles can advantageously be significantly reduced or completely avoided in the case of corresponding optoelectronic components having a housing of this type.

With the screening layer, a housing having a targeted light shading can be realized in particular when a light-transmissive frame is used. With a housing of this type, it is possible to generate a radiation cone whose cross section has an abrupt bright-dark transition on at least one side.

The screening layer is suitable in particular for screening an electromagnetic radiation which encompasses a spectral range of an electromagnetic radiation emitted by a luminescence diode chip, the luminescence diode chip being provided for a component comprising the housing.

The screening layer is particularly preferably suitable for completely screening an electromagnetic radiation, that is to say that the screening layer is particularly preferably opaque to an electromagnetic radiation of a wavelength range to be screened. The wavelength range to be screened may be, in particular, the entire wavelength range of an electromagnetic radiation emitted by a component that is to be produced with the housing. However, it is also possible for the screening layer also to be partly transmissive to electromagnetic radiation. By way of example, it may be partly transmissive to electromagnetic radiation of a wavelength range that is not necessarily to be screened, or else to an electromagnetic radiation to be screened. The electromagnetic radiation to be screened is preferably visible light.

Preferably, the screening layer has, for a wavelength range to be screened of an electromagnetic radiation emitted by a component comprising the housing, a total transmittance of less than or equal to 0.2, particularly preferably of less than or equal to 0.1. Particularly advantageously, said total transmittance is approximately 0 at least for the visible portion of the radiation.

In the present case, the term “screening layer” does not encompass electrical connecting conductors or electrical conductor tracks of the housing. Rather, either the housing is free of electrical conductor tracks or electrical connecting conductors on the outer area or the housing has, at the outer area, at least one screening layer in addition to any electrical connecting conductors or electrical conductor tracks present.

The outer area of the housing advantageously has a partial area facing away from the housing cavity and which is provided with the screening layer. The partial area expediently runs obliquely with respect to a chip mounting plane of the housing.

Advantageously, when a screening layer is present, a part of the outer area that adjoins the output opening is free of it, so that a radiation cone whose cross section has both abrupt and gentle bright-dark transitions can be realized with the housing. Such properties of a radiation cone are of importance in motor vehicle headlights, in particular, in which a relatively abrupt bright-dark transition of the radiation cone is required upwardly and a rather gentler transition from bright to dark in comparison therewith is advantageous downwards or to the side.

The housing cavity particularly advantageously has a small depth. The depth of the housing cavity is preferably less than or equal to 500 μm.

In addition or as an alternative, a housing frame surrounding the housing cavity laterally has a relatively small thickness in a lateral direction which is preferably less than or equal to 1.5 mm, particularly preferably less than or equal to 1.1 mm. The housing frame particularly advantageously has partial regions in which it has a thickness of less than or equal to 0.7 mm in a lateral direction.

In accordance with one particularly expedient embodiment, the housing is suitable for a headlight component, in particular for a motor vehicle headlight component.

A luminescence diode component is specified which has the housing and also at least one luminescence diode chip mounted on the chip mounting region. The housing expediently contains as many luminescence diode chips as there are chip mounting regions.

Preferably, there is arranged in the housing cavity a luminescence conversion material having at least one phosphor that can be excited by an electromagnetic radiation emitted by the luminescence diode chip. Particularly preferably, the phosphor is mixed into a potting composition, which is in turn filled into the housing cavity. The potting composition at least partly fills the housing cavity.

In accordance with a particularly expedient embodiment, the luminescence diode component is a headlight component, in particular for a motor vehicle.

Further advantages, preferred embodiments and developments of the housing and of the component emerge from the exemplary embodiments explained below in conjunction with FIGS. 1 to 6.

### BRIEF DESCRIPTION OF THE DRAWINGS

FIG. 1 shows a schematic plan view of a first exemplary embodiment of the component and the housing,

FIG. 2 shows a schematic sectional view of the component and housing illustrated in FIG. 1,

FIG. 3 shows a schematic plan view of a second exemplary embodiment of the component and the housing,

FIG. 4 shows a schematic sectional view of the component and housing illustrated in FIG. 3,

FIG. 5 shows a schematic plan view of a third exemplary embodiment of the component and the housing, and

FIG. 6 shows a schematic sectional view of the component and housing illustrated in FIG. 5.

In the exemplary embodiments and figures, identical or identically acting constituent parts are in each case provided with the same reference symbols. The elements illustrated in the figures are not necessarily to be regarded as true to scale, rather they may in part be illustrated with an exaggerated size for the sake of better understanding.

### DETAILED DESCRIPTION

The luminescence diode components 2 illustrated in the figures in each case have a housing 1 having a housing cavity 11 in which luminescence diode chips 3 are in each case mechanically and electrically conductively mounted according to the available number of chip mounting regions 33. Each component 2 has five luminescence diode chips 3, by way of example.

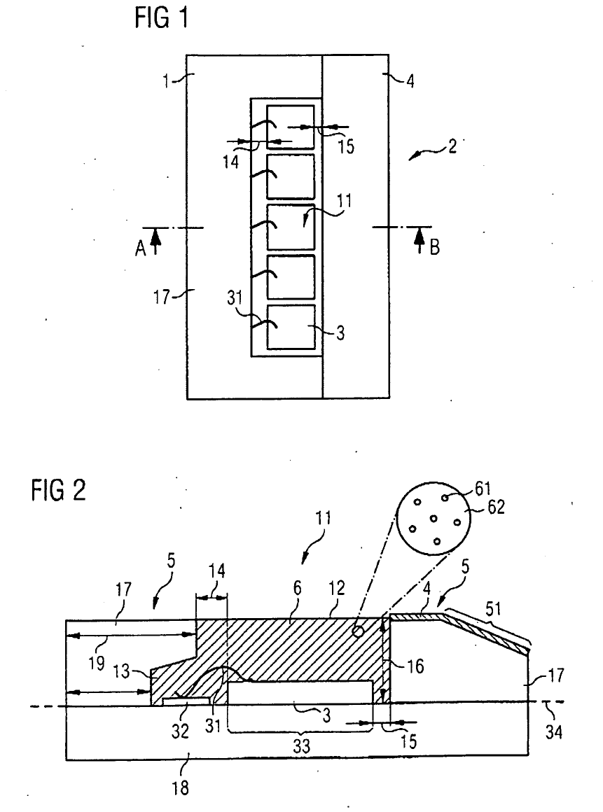

FIGS. 2, 4 and 6 respectively show schematic sectional views of the components illustrated in a plan view in FIGS. 1, 3 and 5. The section for the sectional views runs along the line AB respectively illustrated in FIGS. 1, 3 and 5.

In the case of the components in accordance with the exemplary embodiments, the housing cavities 11 in each case have an output opening 12. The housing cavities are filled with a luminescence conversion material 6 completely, that is to say as far as the output opening 12. As an alternative, the housing cavities 11 may also be only partly filled with a luminescence conversion material 6, with the result that the latter does not reach as far as the output opening 12 of the housing cavity 11.

The luminescence conversion material has a potting composition 62. The latter is based for example on an epoxy resin, on a silicone or on a hybrid material comprising at least two components which contains an epoxy resin and/or a silicone. The potting composition 62 is mixed with at least one phosphor 61. The phosphor can be excited by blue light, for example, and emits a yellow light.

By way of example, a Ce-activated garnet phosphor, for example Ce-activated Tb₃Al₅O₁₂ or Ce-activated Y₃Al₅O₁₂, is suitable as phosphor. In principle, all organic and inorganic phosphors which are known for a use in combination with luminescence diode chips are suitable. It is also possible to use a plurality of phosphors, in which case not only is it possible for the plurality of phosphors to emit different colours, but it is also possible for the phosphors to emit different hues of the same colour. By way of example, a plurality of phosphors which emit different yellow hues are contained. Consequently, the emission spectra of the phosphors can advantageously overlap.

The luminescence diode chips are semiconductor light-emitting diode chips, by way of example. They are based on nitride compound semiconductor materials, by way of example. These are to be understood to mean compound semiconductor materials which contain nitrogen, such as e.g. materials from the system InₓAl_{y}Ga_{1-x-y}N where 0≦x≦1, 0≦y≦1 and x+y≦1. The luminescence diode chips expediently have an epitaxially grown semiconductor layer sequence containing at least one individual layer with a nitride compound semiconductor material. The semiconductor layer sequence may have for example a conventional pn junction, a double heterostructure, a single quantum well structure (SQW structure) or a multi quantum well structure (MQW structure). Such structures are known to the person skilled in the art and are therefore not explained in any greater detail at this point.

As an alternative, the luminescence diode chips 3 may also be based on a different material system. In principle, it is also possible to use organic light-emitting diodes in the component.

The housings have a carrier 18 in all the exemplary embodiments. In the case of the exemplary embodiments illustrated in FIGS. 1 to 4, the luminescence diode chips 3 are mechanically and electrically conductively mounted with their side facing the housing carrier 18 for example by means of an electrically conductive adhesive or by means of a solder. In these exemplary embodiments, the luminescence diode chips 3 also have an electrical contact area (not shown) on their side facing the output opening 12. Said electrical contact area is electrically conductively connected to a corresponding electrical contact area 32 of the housing 1 by means of a bonding wire 31.

The electrical contact area 32 is arranged on the bottom of the housing cavity 11. It adjoins the housing carrier 18, on which a housing frame 17 is applied. The housing carrier 18 and the housing frame 17 in each case comprise a separate part, but they may alternatively also be formed jointly, from a single part.

In the case of the exemplary embodiment illustrated in FIG. 2, a part of the frame projects laterally above a partial region 13 of the housing cavity 11. This part of the frame also projects laterally above a part of the electrical connecting area 32. The partial region 13 above which the housing frame projects laterally and the corresponding part of the electrical connecting area 32 are also offset laterally with respect to the output opening 12 of the housing cavity 11.

The remaining part of the housing cavity 11 laterally overlaps the output opening 12 completely. It adjoins inner walls of the housing frame which essentially run perpendicular to a chip mounting plane 34 of the housing 1. Said inner walls of the housing cavity are at a maximum lateral distance 14 of 350 μm, for example, from the chip mounting region 33. The maximum lateral distance 14 from the chip mounting regions 33 is equal to the maximum distance 14 from the luminescence diode chips 3.

The inner walls are at a minimum distance 15 of 150 μm, for example, from the chip mounting regions 33 and the luminescence diode chips 3. As an alternative, the minimum distance may for example have a magnitude of approximately only 50 μm. The housing cavity has for example a depth 16 of only 500 μm.

The housing frame 17 comprises for example a material which is not transparent but is transmissive to visible light. In the thickest regions, the housing frame 17 has a transmission to light of approximately 40% for example in a lateral direction. The maximum thickness 19 of the housing frame is for example 1.05 mm in a lateral direction. That part of the housing frame 17 which laterally projects above the partial region 13 of the housing cavity has for example a transmission to visible light of approximately 70% in a vertical direction.

At the thinnest locations, the housing frame 17 has a thickness 190 of approximately 500 μm, for example, in a lateral direction.

The housing frame 17 comprises a ceramic material, for example, or has such a material. A suitable material is aluminium oxide (Al₂O₃) for example. As an alternative, the frame 17 has for example aluminium nitride, glass ceramic, glass or at least one plastic.

The frame 17 may in particular comprise a plastic or have such a plastic which has a coefficient of thermal expansion similar to that of a material of the carrier 18. The housing carrier 18 may for example also have metal or comprise such a metal. By way of example, copper is well suited on account of its high thermal conductivity. As an alternative, the housing carrier 18 may comprise for example the same material as the housing frame 17.

The luminescence diode chips 3 are mounted in a linear arrangement in the housing 1. The arrangement runs along a straight line. As an alternative, the linear arrangement may also run along an arbitrarily shaped line, for example along a curved line or a bent line. The luminescence diode chips are particularly advantageously arranged along a line having a bend, the line segments that are inclined with respect to one another being at an angle of approximately 165° with respect to one another. In other words, the line comprises two partial straight lines that are inclined by approximately 15° with respect to one another.

On an outer area 5 adjoining the output opening 12 of the housing cavity 11, the housing frame is provided with a screening layer 4. The screening layer 4 is contained on one side of the outer area 5 of the housing frame 17. On a side of the housing frame that is opposite to said side, the outer area 5 is free of the screening layer 4.

The outer area 5 provided with the screening layer 4 has a partial area 51 inclined away from the housing cavity 11. Said partial area is preferably also spaced apart from the housing cavity. An embodiment of this type is advantageous both for the application of the screening layer and for the screening effect obtained by means of the screening layer.

The screening layer 4 comprises a reflective material, for example, having metallic material such as silver, for example. In order to form the screening layer, e.g. a silver layer is applied with a sufficiently high layer thickness on the corresponding layers of the housing. Silver has a high reflectivity for a large spectral range of visible light. The silver layer may be only a few monolayers thick in order that it is still partly transmissive to electromagnetic radiation in a targeted manner. In order to obtain a complete screening, the thickness must be significantly greater. For this purpose, it has a thickness of 10 μm, for example.

In addition or as an alternative, the screening layer 4 may for example also have absorbent material. By way of example, metallic material having predominantly absorbent properties for an envisaged spectral range is likewise appropriate for this purpose. In the case of the absorbent material, too, it is important for said material not to be applied in an excessively thin layer, if an electromagnetic radiation generated in the interior of the housing is intended to be screened to the greatest possible extent. The screening layer has a total transmittance of less than or equal to 0.05, for example, for a wavelength range to be screened. By way of example, lacquers or plastics are also appropriate as absorbent material.

In accordance with a further exemplary embodiment, the screening layer 3 has a reflective layer which is applied on the outer area 5 and on which in turn an absorbent layer is applied. The absorbent layer is for example a black lacquer or a black plastic. These are absorbent in particular for visible electromagnetic radiation. As an alternative, the screening layer 3 may for example also comprise only a sufficiently thick black lacquer layer or black plastic layer.

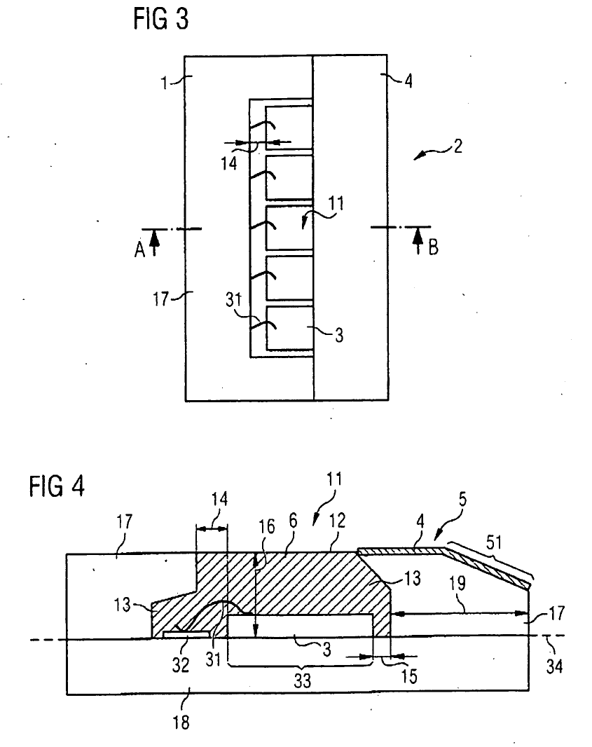

In the case of the exemplary embodiment illustrated in FIGS. 3 and 4, the housing cavity 11 has two partial regions 13 that are laterally covered by housing material. A part of the luminescence diode chip 3 is arranged in one of said partial regions 13, so that a part of the chip mounting region 33 is also correspondingly covered laterally by housing material. Said partial region 13 and the part of the luminescence diode chip or of the chip mounting region 33 are additionally also covered laterally by the screening layer 4 in the exemplary embodiment illustrated.

A part of the housing margin that bounds the output opening 12 completely overlaps the chip mounting region 33, that is to say that it is arranged above the chip mounting region 33. A further part of said margin is at a maximum distance 14 of, for example, 300 μm from the chip mounting region 33 or the luminescence diode chip 3.

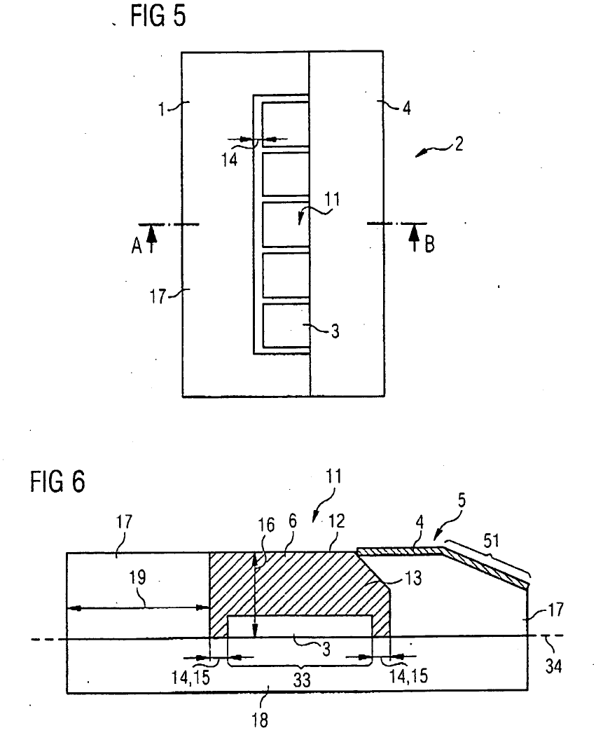

In the case of the exemplary embodiment illustrated in FIGS. 5 and 6, the chip mounting region 33 is likewise partly covered laterally by a part of the frame. In contrast to the exemplary embodiments described with reference to FIGS. 1 to 4, the housing illustrated in FIGS. 5 and 6 has no electrical connecting area 32 arranged alongside the chip mounting region 33. On the corresponding side, the inner wall of the housing cavity 11 is formed such that it is straight and runs essentially perpendicular to the chip mounting plane 34. In this embodiment, the maximum distance 14 from the luminescence diode chip 3 can be chosen to be even smaller. It is 150 μm or 100 μm, by way of example.

This embodiment illustrated in FIGS. 5 and 6 is suitable in particular for luminescence diode chips which have both electrical connections on the same side, as is the case for example with so-called flip-chips. In the case of luminescence diode chips 3 of this type, both electrical connections can be electrically conductively connected directly to corresponding electrical connections on the chip carrier 18 that are arranged within the chip mounting region 33, and on which the luminescence diode chip 3 bears. Consequently, overall the housing cavity can be formed such that it is even narrower along the chip mounting plane 34.

The scope of protection of the invention is not restricted by the description of the exemplary embodiments to the latter. Thus, by way of example, it is not absolutely necessary to arrange a plurality of luminescence diode chips in a single row. Rather, it is also possible to arrange them in two or even more rows, for example. The invention encompasses any new feature and also any combination of features, which in particular comprises any combination of features in the patent claims, even if this feature or this combination itself is not explicitly specified in the patent claims or the exemplary embodiments.

1. A housing for a luminescence diode component, the housing comprising:
a housing cavity within which is arranged at least one chip mounting region for a luminescence diode chip and which has an output opening,
wherein the housing has, at least at a vertical distance from the chip mounting region, inner walls which laterally bound the housing cavity and are at a maximum lateral distance of less than or equal to 500 μm from the chip mounting region.

2. The housing according to claim 1, wherein the housing cavity has at least one partial region which is laterally covered by a housing material that laterally delimits the housing cavity.

3. A housing for a luminescence diode component, the housing comprising:
a housing cavity within which is arranged at least one chip mounting region for a luminescence diode chip and which has an output opening,
wherein the housing cavity has at least one partial region which is laterally covered by a housing material that laterally delimits the housing cavity.

4. The housing according to claim 3, wherein the housing has, at least at a vertical distance from the chip mounting region, inner walls which laterally bound the housing cavity and are at a maximum lateral distance of less than or equal to 500 μm from the chip mounting region.

5. The housing according to claim 2, wherein the partial region is offset laterally with respect to the output opening.

6. The housing according to claim 2, wherein the partial region adjoins a chip mounting plane of the housing.

7. The housing according to claim 1, wherein an electrical contact area for electrically conductively contact-connecting a luminescence diode chip is contained within the housing cavity, at least one part of the electrical contact area being laterally covered by a housing materials that laterally delimits the housing cavity.

8. The housing according to one claim 1, wherein a part of the chip mounting region is offset laterally with respect to the output opening.

9. The housing according to claim 1, wherein a plurality of chip mounting regions are contained which are arranged in a linear arrangement with respect to one another.

10. The housing according to claim 1, wherein a frame that laterally delimits the housing cavity is contained, which frame is at least partly light-transmissive.

11. The housing according to claim 1, wherein a frame that laterally bounds the housing cavity has, in a vertical lateral direction, a transmissivity to light of between 20% and 80% inclusive.

12. The housing according to claim 1, wherein an outer area of the housing which adjoins the output opening of the housing cavity is provided with a screening layer suitable for screening electromagnetic radiation.

13. The housing according to claim 8, wherein a part of the outer area that adjoins the output opening is free of the screening layer.

14. The housing according to claim 8, wherein the outer area of the housing has a partial area facing away from the housing cavity and which is provided with the screening layer.

15. The housing according to claim 1, wherein the housing cavity has a depth of less than or equal to 500 μm.

16. The housing according to claim 1, wherein a housing frame that laterally surrounds the housing cavity has a thickness of less than or equal to 1.5 mm.

17. The housing according to claim 1, wherein it is suitable for a headlight component.

18. A luminescence diode component, wherein it has a housing according to claim 1 and at least one luminescence diode chip which is mounted on the chip mounting region.

19. A luminescence diode component having a housing according to claim 15, wherein a luminescence conversion material having at least one phosphor that can be excited by an electromagnetic radiation emitted by the luminescence diode chip is arranged in the housing cavity.

20. A luminescence diode component having a housing according to claim 16, wherein the housing cavity is at least partly filled with a potting composition into which the phosphor is mixed.

21. The housing according to claim 15, wherein the luminescence diode component is a headlight component.
